(19) United States
(12) Patent Application Publication
(10) Pub. No.: US 2020/0241331 A1
(43) Pub. Date: Jul. 30, 2020

(54) DRIVING CIRCUIT FOR OPTICAL MODULATOR

(71) Applicant: SUMITOMO ELECTRIC INDUSTRIES, LTD., Osaka (JP)

(72) Inventor: Taizo TATSUMI, Osaka (JP)

(73) Assignee: SUMITOMO ELECTRIC INDUSTRIES, LTD., Osaka (JP)

(21) Appl. No.: 16/774,110

(22) Filed: Jan. 28, 2020

(30) Foreign Application Priority Data
Jan. 30, 2019 (JP) 2019-014514

(51) Int. Cl. G02F 1/01; H03K 3/0234; H03F 3/45; H03F 3/68

(52) U.S. Cl. CPC G02F 1/0121; H03K 3/0234; H03F 3/45085; H03F 2203/45116; H03F 2203/45026; H03F 2203/45022; H03F 2203/45034; H03F 3/68

(57) ABSTRACT

A driving circuit includes a first differential amplifier, wherein the first differential amplifier includes: a delay adjustment circuit that generates a second differential signal by delaying a first differential signal in response to instantaneous voltage level of the first differential signal; a differential circuit that divides a source current into a first current and a second current in response to the second differential signal; and a first load resistor and a second load resistor that generate a positive phase component and a negative phase component of the differential output signal based on the first current and the second current, wherein a third differential amplifier operates in a non-saturated region when a voltage level of the first differential signal is in an input voltage range, and operates in a saturated region when the voltage level of the first differential signal is out of the input voltage range.

### TECHNICAL FIELD

The present disclosure relates to a driving circuit for an optical modulator.

This application claims priority based on Japanese Patent Application No. 2019-14514 filed on Jan. 30, 2019, and incorporates all the content described in the Japanese patent application.

### BACKGROUND

An optical transmission module used in optical communication includes an optical modulator and a driving circuit for the optical modulator (see Japanese Unexamined Patent Publication No. 2015-172681). In recent years, with an increase in capacity and speed of an optical transmission, the driving circuit is required to have a high modulating speed of about 28 Gbaud to 56 Gbaud. In order to realize such the high modulating speed, a multi-level modulation system such as 4-level pulse amplitude modulation (PAM4) instead of a binary modulation system such as non-return to zero (NRZ) may be adopted.

However, in the driving circuit corresponding to the multi-level modulation system, a time constant (or a response speed) of a circuit can change according to a voltage level of a signal. For this reason, timings at which the signal reaches respective voltage levels are different from each other, and a waveform quality may be deteriorated.

The present disclosure provides a driving circuit for an optical modulator capable of improving a waveform quality of a pulse amplitude modulation signal.

### SUMMARY

A driving circuit for an optical modulator according to one aspect of the present disclosure generates a driving signal for an optical modulator in response to a differential input signal having a positive phase component and a negative phase component. The driving circuit includes: a first differential amplifier configured to generate a differential output signal in response to a difference between the positive phase component and the negative phase component of the differential input signal, the differential output signal having a positive phase component and a negative phase component; and a second differential amplifier configure to generate the driving signal in response to the differential output signal. The first differential amplifier includes: an emitter follower configured to generate a first differential signal by lowering voltage level of the differential input signal, the first differential signal having a positive phase component and a negative phase component; a delay adjustment circuit configured to generate a second differential signal by delaying the first differential signal in response to instantaneous voltage level of the first differential signal, the second differential signal having a positive phase component and a negative phase component; a current source configured to supply a source current; a differential circuit configured to divide the source current into a first current and a second current, the first current and the second current varying complementarily in response to a difference between the positive phase component of the second differential signal and the negative phase component of the second differential signal; a first load resistor configured to generate the positive phase component of the differential output signal based on the first current; and a second load resistor configured to generate the negative phase component of the differential output signal based on the second current. The delay adjustment circuit includes: a positive phase input node configured to receive the positive phase component of the first differential signal; a negative phase input node configured to receive the negative phase component of the first differential signal; a positive phase output node configured to output the positive phase component of the second differential signal; a negative phase output node configured to output the negative phase component of the second differential signal; a first resistor electrically connected between the positive phase input node and the positive phase output node; a second resistor electrically connected between the negative phase input node and the negative phase output node; a first capacitor; a second capacitor; and a third differential amplifier having a non-inverting input node, an inverting input node, a non-inverting output node, and an inverting output node, the non-inverting input node being electrically connected between the second resistor and the negative phase output node, the inverting input node being electrically connected between the first resistor and the positive phase output node, the non-inverting output node being electrically connected to the inverting input node through the second capacitor, the inverting output node being electrically connected to the non-inverting input node through the first capacitor. The first differential signal has a voltage level including a first voltage level, a second voltage level higher than the first voltage level, a third voltage level higher than the second voltage level, and a fourth voltage level higher than the third voltage level. The third differential amplifier operates in a non-saturated region, when the voltage level of the first differential signal is in an input voltage range, and the third differential amplifier operates in a saturated region, when the voltage level of the first differential signal is out of the input voltage range. The input voltage range is a voltage range from a first voltage value to a second voltage value, the first voltage value being set to be higher than the first voltage level and lower than the second voltage level, the second voltage value being set to be higher than the third voltage level and lower than the fourth voltage level.

### BRIEF DESCRIPTION OF THE DRAWINGS

FIG. 1 is a diagram schematically showing a configuration of an optical transmission module including a driving circuit for an optical modulator according to an embodiment;

FIG. 2 is a diagram schematically showing a configuration of the driving circuit shown in FIG. 1;

FIG. 3 is a diagram showing a circuit configuration of a pre-buffer circuit shown in FIG. 2;

FIG. 4 is a diagram showing an input operation range of a limiting amplifier shown in FIG. 3;

FIG. 5 is a diagram showing an example of a circuit configuration of the limiting amplifier shown in FIG. 3;

FIG. 6 is a diagram showing another example of the circuit configuration of the limiting amplifier shown in FIG. 3;

FIG. 7 is a diagram showing a circuit configuration of an output buffer circuit shown in FIG. 2;

FIG. 8A is an equivalent circuit diagram of a single phase side of the output buffer circuit shown in FIG. 7;

FIG. 8B is a diagram illustrating a time constant of a transistor for switching;

FIG. 8C is a diagram illustrating a time constant of a cascode transistor;

FIG. 9A is a diagram showing an example of a differential output signal output from the pre-buffer circuit shown in FIG. 2;

FIG. 9B is a diagram showing an example of a differential output signal output from a pre-buffer circuit according to a comparative example;

FIG. 10A is a diagram showing an example of a driving signal output from the driving circuit shown in FIG. 2;

FIG. 10B is a diagram showing an example of a driving signal output from a driving circuit for an optical modulator according to a comparative example; and

FIG. 11 is a diagram showing a modification of the circuit configuration of the pre-buffer circuit shown in FIG. 2.

### DETAILED DESCRIPTION

A specific example of a driving circuit for an optical modulator according to an embodiment of the present disclosure will be described below with reference to the drawings. It should be noted that the present disclosure is not limited to these examples, and is intended to include all modifications within the spirit and scope as defined by the appended claims and their equivalents.

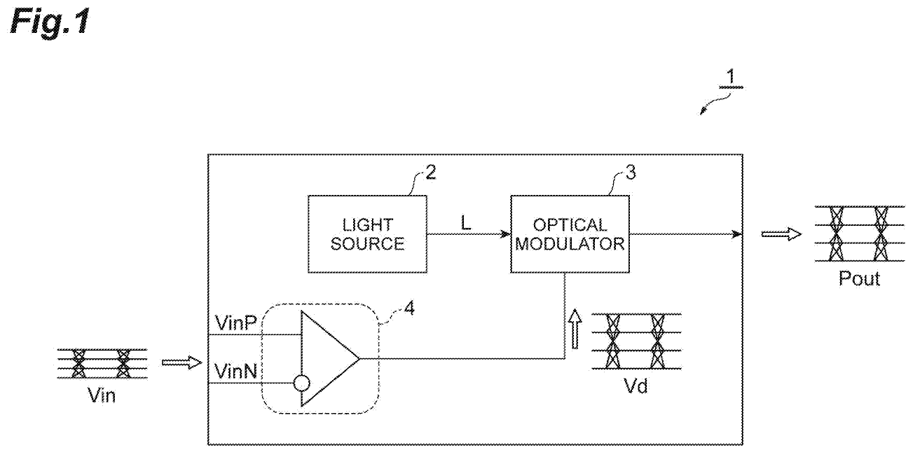

FIG. 1 is a diagram schematically showing a configuration of an optical transmission module including a driving circuit for an optical modulator according to an embodiment. As shown in FIG. 1, an optical transmission module 1 is a device that outputs an optical signal Pout according to a differential input signal Vin. The optical transmission module 1 includes a light source 2, an optical modulator 3, and a driving circuit 4. The light source 2 outputs continuous light (CW light) L having a predetermined peak wavelength. An example of the light source 2 is a laser diode. The optical modulator 3 generates the optical signal Pout by modulating the continuous light L output from the light source 2 according to a driving signal Vd output from the driving circuit 4. Examples of the optical modulator 3 include an electro-absorption modulator (EAM) and a Mach-Zehnder modulator (MZM). The driving circuit 4 is a driving circuit for driving the optical modulator 3, and is a driving circuit for outputting the driving signal Vd according to the differential input signal Vin. The differential input signal Vin has a positive phase component VinP and a negative phase component VinN.

The positive phase component VinP has a phase that is 180° different from a phase of the negative phase component VinN. For example, the negative phase component VinN decreases when the positive phase component VinP increases, and the negative phase component VinN increases when the positive phase component VinP decreases. When the positive phase component VinP reaches a maximum value (peak value), the negative phase component VinN reaches a minimum value (bottom value), and when the positive phase component VinP reaches the bottom value, the negative phase component VinN reaches the peak value. The peak value of the positive phase component VinP and the peak value of the negative phase component VinN are substantially equal to each other, and the bottom value of the positive phase component VinP and the bottom value of the negative phase component VinN are substantially equal to each other.

Therefore, the positive phase component VinP and the negative phase component VinN have the same amplitude. In the following description, for other differential signals, a relation between a positive phase component and a negative phase component is the same as a relation between the positive phase component VinP and the negative phase component VinN.

In the present embodiment, the differential input signal Vin, the driving signal Vd, and the optical signal Pout are PAM4 signals. That is, each signal has four logic levels of Level-0 to Level-3. Levels 0 to 3 increase in the order of Level-0, Level-1, Level-2, and Level-3. That is, Level-0 is the lowest logic level and Level-3 is the highest logic level.

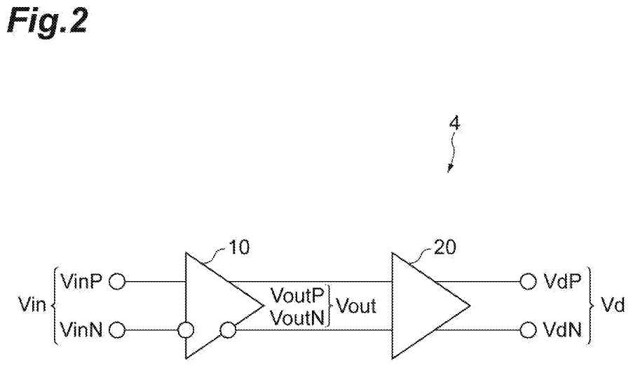

FIG. 2 is a diagram schematically showing a configuration of the driving circuit shown in FIG. 1. As shown in FIG. 2, the driving circuit 4 includes a pre-buffer circuit 10 (first differential amplifier) and an output buffer circuit 20 (second differential amplifier). The pre-buffer circuit 10 is a differential amplifier that receives the differential input signal Vin from the outside of the optical transmission module 1 and generates a differential output signal Vout according to the difference between the positive phase component VinP and the negative phase component VinN. The differential output signal Vout has a positive phase component VoutP and a negative phase component VoutN. The pre-buffer circuit 10 outputs the differential output signal Vout to the output buffer circuit 20. The differential output signal Vout has an amplitude necessary for driving the output buffer circuit 20, and the amplitude is, for example, about 0.3 Vpp.

The output buffer circuit 20 is a differential amplifier that receives the differential output signal Vout output from the pre-buffer circuit 10 and generates the driving signal Vd according to the differential output signal Vout. The output buffer circuit 20 outputs the driving signal Vd to the optical modulator 3. The driving signal Vd has an amplitude necessary for driving the optical modulator 3. The driving signal Vd is a differential signal, and has a positive phase component VdP and a negative phase component VdN. A voltage amplitude of each of the positive phase component VdP and the negative phase component VdP is, for example, 0.8 Vpp to 2.5 Vpp. A current amplitude of each of the positive phase component VdP and the negative phase component VdP is, for example, 40 mApp to 100 mApp.

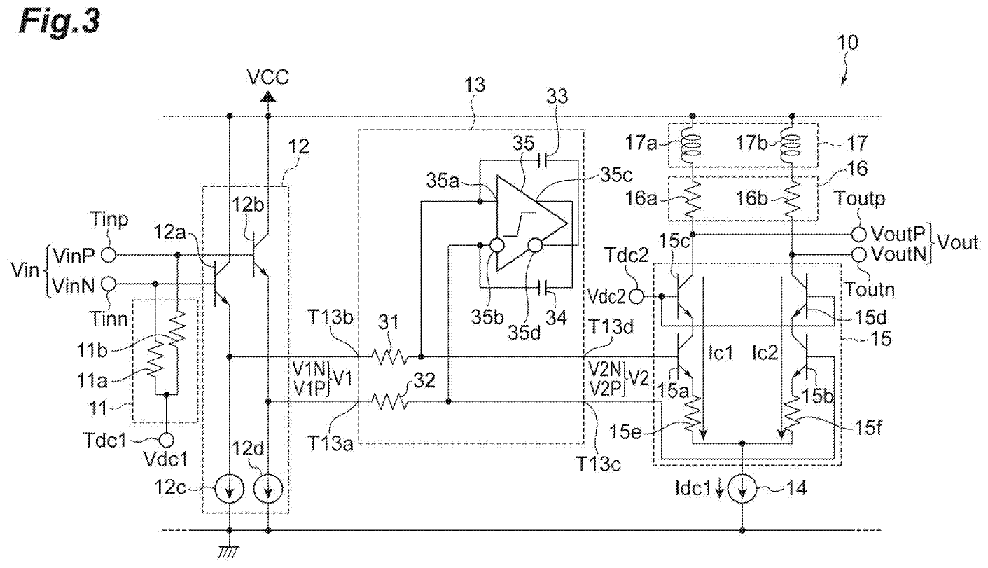

FIG. 3 is a diagram showing a circuit configuration of the pre-buffer circuit shown in FIG. 2. As shown in FIG. 3, the pre-buffer circuit 10 has a terminal Tinp, a terminal Tinn, a terminal Toutp, a terminal Toutn, a terminal Tdc1, and a terminal Tdc2. The positive phase component VinP is input to the terminal Tinp. The negative phase component VinN is input to the terminal Tinn. The terminal Toutp outputs the positive phase component VoutP. The terminal Toutn outputs the negative phase component VoutN. A DC potential Vdc1 generated in the driving circuit 4 is supplied to the terminal Tdc1. A DC potential Vdc2 (bias voltage) generated in the driving circuit 4 is supplied to the terminal Tdc2.

The pre-buffer circuit 10 includes an input termination circuit 11, an emitter follower 12, a delay adjustment circuit 13, a current source 14, a differential circuit 15, a load circuit 16, and a compensation circuit 17.

The input termination circuit 11 includes a resistor (resistive element) 11a and a resistor 11b. The resistor 11a and the resistor 11b are input termination resistors. One end of the resistor 11a is electrically connected to the terminal Tinn, and the other end of the resistor 11a is electrically connected to the terminal Tdc1. One end of the resistor 11b is electrically connected to the terminal Tinp, and the other end of the resistor 11b is electrically connected to the terminal Tdc1. Resistance values of the resistor 11a and the resistor 11b are, for example, about 50 Ω. In order to transmit the differential input signal Vin from an external circuit (not shown) to the driving circuit 4, a pair of transmission lines (not shown) may be electrically connected to the terminals Tinp and Tinn. In this case, the resistance values of the resistor 11a and the resistor 11b may be set according to the characteristic impedance of the transmission lines. For example, the resistance values of the resistor 11a and the resistor 11b may be set in a range of 25 to 60 Ω.

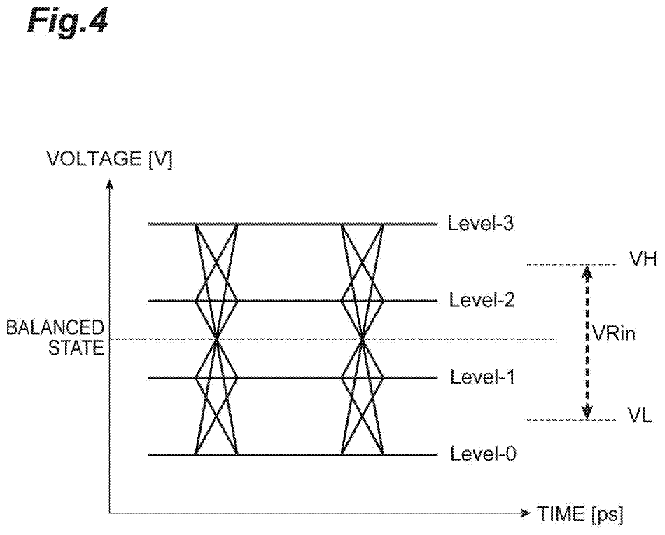

The emitter follower 12 is a circuit that generates the differential signal V1 (first differential signal) by lowering a voltage level of the differential input signal Vin. The differential signal V1 has a positive phase component V1P and a negative phase component V1N. As shown in FIG. 4, the differential signal V1 is a PAM4 signal, and includes four voltage levels (logic levels) of Level-0 to Level-3, similarly to the differential input signal Vin. Level-0 and Level-3 are symmetric around an average voltage (balanced state) of the differential signal V1. Level-1 and Level-2 are symmetric around the average voltage (balanced state) of the differential signal V1. The other PAM4 signals have the same waveforms. For example, when the voltages of Level-0 to Level-3 are set as V_0 to V_3, respectively, and the average voltage is set as Va, V_3−Va=Va−V_0 and V_2−Va=Va−V_1 are obtained in the above symmetry.

The emitter follower 12 includes a transistor 12a, a transistor 12b, a current source 12c, and a current source 12d. The transistors 12a and 12b are, for example, NPN bipolar transistors. As the bipolar transistor, a heterojunction bipolar transistor (HBT) may be used. A base of the transistor 12a is electrically connected to the terminal Tinn. A collector of the transistor 12a is electrically connected to a power supply wiring that supplies a power supply voltage VCC. An emitter of the transistor 12a is electrically connected to one end of the current source 12c. A base of the transistor 12b is electrically connected to the terminal Tinp. A collector of the transistor 12b is electrically connected to the power supply wiring that supplies the power supply voltage VCC. An emitter of the transistor 12b is electrically connected to one end of the current source 12d. The current source 12c is a constant current source, and the other end of the current source 12c is connected to a ground potential. The current source 12d is a constant current source, and the other end of the current source 12d is connected to the ground potential.

The transistor 12a and the current source 12c configure an emitter follower unit. This emitter follower unit receives the negative phase component VinN, lowers the voltage level of the negative phase component VinN, and outputs the negative phase component VinN whose voltage level has been lowered to the delay adjustment circuit 13 as the negative phase component V1N. The transistor 12b and the current source 12d configure an emitter follower unit. This emitter follower unit receives the positive phase component VinP, lowers the voltage level of the positive phase component VinP, and outputs the positive phase component VinP whose voltage level has been lowered to the delay adjustment circuit 13 as the positive phase component V1P.

The delay adjustment circuit 13 is a circuit that generates a differential signal V2 (second differential signal) by delaying the differential signal V1 by a delay amount according to the voltage level of the differential signal V1. The differential signal V2 has a positive phase component V2P and a negative phase component V2N. The differential signal V2 is a PAM4 signal having the same amplitude as the differential signal V1, and includes four voltage levels (logic levels) of Level-0 to Level-3, similarly to the differential signal V1.

The delay adjustment circuit 13 has a positive phase input node T13a, a negative phase input node T13b, a positive phase output node T13c, and a negative phase output node T13d. The positive phase input node T13a is electrically connected to the emitter of the transistor 12b, and the positive phase component V1P of the differential signal V1 is input to the positive phase input node T13a. The negative phase input node T13b is electrically connected to the emitter of the transistor 12a, and the negative phase component V1N of the differential signal V1 is input to the negative phase input node T13b. The positive phase output node T13c outputs the positive phase component V2P of the differential signal V2 to the differential circuit 15. The negative phase output node T13d outputs the negative phase component V2N of the differential signal V2 to the differential circuit 15.

The delay adjustment circuit 13 includes, for example, a resistor 31 (second resistor), a resistor 32 (first resistor), a capacitor 33 (first capacitor), a capacitor 34 (second capacitor), and a limiting amplifier 35 (third differential amplifier). The resistor 31 is electrically connected between the negative phase input node T13b and the negative phase output node T13d. The resistor 32 is electrically connected between the positive phase input node T13a and the positive phase output node T13c. Resistance values of the resistors 31 and 32 are, for example, 5 Ωto 50 Ω.

The limiting amplifier 35 performs a limiting operation in an input operation range VRin (see FIG. 4). That is, the limiting amplifier 35 operates in a non-saturated region (linear amplification) when the voltage level of the differential signal V1 is in the input operation range VRin, and operates in a saturated region when the voltage level of the differential signal V1 is outside the input operation range VRin. The input operation range VRin is a range from a voltage VL (first voltage) to a voltage VH (second voltage). The voltage VL is larger than Level-0 and is smaller than Level-1. The voltage VH is larger than Level-2 and is smaller than Level-3. The input operation range VRin is set at a predetermined ratio with respect to a maximum amplitude of the differential signal V1, for example. The maximum amplitude of the differential signal V1 is a difference between the voltage level of Level-3 and the voltage level of Level-0. For example, the input operation range VRin is set to 30% to 70% of the maximum amplitude of the differential signal V1 with the average voltage of the differential signal V1 as the center. For example, for the voltage level of the differential signal V1, when Level-0 is 0% and Level-3 is 100%, the average voltage Va is 50%, the voltage VL is 15 to 35%, and the voltage VH is 65 to 85%. Here, the voltages VH and VL are set to satisfy VH−Va=Va−VL.

The gain (differential voltage gain) of the limiting amplifier 35 is about 2 to 20. The limiting amplifier 35 has a non-inverting input node 35a, an inverting input node 35b, a non-inverting output node 35c, and an inverting output node 35d. The non-inverting input node 35a is electrically connected between the resistor 31 and the negative phase output node T13d. The inverting input node 35b is electrically connected between the resistor 32 and the positive phase output node T13c. The non-inverting output node 35c is electrically connected to the inverting input node 35b via the capacitor 34. That is, the capacitor 34 connects the non-inverting output node 35c and the inverting input node 35b with negative feedback. The inverting output node 35d is electrically connected to the non-inverting input node 35a via the capacitor 33. That is, the capacitor 33 connects the inverting output node 35d and the non-inverting input node 35a with negative feedback. Capacitance values of the capacitors 33 and 34 are, for example, 5 fF to 50 if.

The current source 14 is a circuit that supplies a direct current Idc1. The current source 14 supplies the direct current Idc1 to the differential circuit 15.

The differential circuit 15 is a circuit that divides the direct current Idc1 into a current signal Ic1 (first current signal) and a current signal Ic2 (second current signal), according to the difference between the positive phase component V2P and the negative phase component V2N. That is, the differential circuit 15 divides the direct current Idc1 into two current signals according to the difference between the positive phase component V2P and the negative phase component V2N, and generates a differential current signal (the current signal Ic1 and the current signal Ic2). The differential circuit 15 includes a transistor 15a (first transistor), a transistor 15b (second transistor), a transistor 15c (third transistor), a transistor 15d (fourth transistor), a resistor 15e, and a resistor 15f.

The transistors 15a to 15d are, for example, NPN bipolar transistors. A heterojunction bipolar transistor may be used as the bipolar transistor. The transistors 15a and 15b are transistors for switching. For example, the transistor for switching is a transistor with good high frequency characteristics, which has a cutoff frequency higher than an upper limit of a frequency band required by a signal amplified by the transistor. A base of the transistor 15a is electrically connected to the negative phase output node T13d of the delay adjustment circuit 13, and the negative phase component V2N is input to the base of the transistor 15a. An emitter of the transistor 15a is electrically connected to the current source 14 via the resistor 15e. A collector of the transistor 15a is electrically connected to an emitter of the transistor 15c, and outputs the current signal Ic1. A base of the transistor 15b is electrically connected to the positive phase output node T13c of the delay adjustment circuit 13, and the positive phase component V2P is input to the base of the transistor 15b. An emitter of the transistor 15b is electrically connected to the current source 14 via the resistor 15f. A collector of the transistor 15b is electrically connected to an emitter of the transistor 15d and outputs the current signal Ic2. The transistors 15a and 15b may have the same electrical characteristics, or may be formed by the same transistor structure so as to have the same electrical characteristics. The transistors 15a and 15b may be manufactured by the same semiconductor process on one semiconductor chip.

The transistors 15c and 15d are cascode transistors. A base of the transistor 15c is electrically connected to the terminal Tdc2, and the DC potential Vdc2 is applied to the base of the transistor 15c. A collector of the transistor 15c is electrically connected to the load circuit 16 and is electrically connected to the terminal Toutp. A base of the transistor 15d is electrically connected to the terminal Tdc2, and the DC potential Vdc2 is applied to the base of the transistor 15d. A collector of the transistor 15d is electrically connected to the load circuit 16 and is electrically connected to the terminal Toutn. The transistors 15c and 15d may have the same electrical characteristics, or may be formed by the same transistor structure so as to have the same electrical characteristics. The transistors 15c and 15d may be manufactured by the same semiconductor process on one semiconductor chip.

The resistors 15e and 15f are resistive elements for a linear operation. The transistor 15a operates in a region where an emitter current of the transistor 15a is not turned off by the resistor 15e. Similarly, the transistor 15b operates in a region where an emitter current of the transistor 15b is not turned off by the resistor 15f. If the resistance values of the resistors 15e and 15f are increased, a differential voltage gain of the differential output signal Vout with respect to the differential signal V2 is decreased. If the resistance values of the resistors 15e and 15f are decreased, the differential voltage gain of the differential output signal Vout with respect to the differential signal V2 is increased. By setting the resistance values of the resistors 15e and 15f to the appropriate magnitudes, it is possible to prevent the differential output signal Vout from being saturated with respect to an increase in the differential signal V2. The resistance values of the resistors 15e and 15f may be set to the same value (this value will be represented as R_{EPB}). In the differential circuit 15, the current signal Ic1 flows to the transistor 15c, the transistor 15a, and the resistor 15e. The current signal Ic2 flows to the transistor 15d, the transistor 15b, and the resistor 15f.

The load circuit 16 is a circuit that converts the differential current signal (the current signal Ic1 and the current signal Ic2) into the differential output signal Vout. The load circuit 16 includes a load resistor 16a (first load resistor) and a load resistor 16b (second load resistor). One end of the load resistor 16a is electrically connected to the collector of the transistor 15c. The other end of the load resistor 16a is electrically connected to the compensation circuit 17. The load resistor 16a generates the positive phase component VoutP of the differential output signal Vout on the basis of the current signal Ic1. In the present embodiment, the load resistor 16a converts the current signal Ic1 into the positive phase component VoutP. Specifically, the collector potential of the transistor 15c generated by the current signal Ic1 flowing to the load resistor 16a is output from the terminal Toutp as the positive phase component VoutP.

For example, when a current value of the current signal Ic1 is zero, a voltage level of the positive phase component VoutP becomes the upper limit VlimitH, and VlimitH=VCC is satisfied. When the current value of the current signal Ic1 is equal to a current value of the direct current Idc1, the voltage level of the positive phase component VoutP becomes the lower limit VlimitL, and VlimitL=VCC−Idc1><R_{L} is satisfied. Here, R_{L} represents the resistance value of the load resistor 16a. If the voltage level of the positive phase component VoutP reaches the upper limit VlimitH or the lower limit VlimitL, the positive phase component VoutP is saturated. Therefore, in order to ensure that the voltage level of the positive phase component VoutP always changes linearly with respect to a change in the differential input signal Vin, the direct current Idc1 and the resistance values R_{L} and R_{EPB} are set so that the voltage level of the positive phase component VoutP is higher than the lower limit VlimitL and lower than the upper limit VlimitH.

One end of the load resistor 16b is electrically connected to the collector of the transistor 15d. The other end of the load resistor 16b is electrically connected to the compensation circuit 17. The load resistor 16b generates a negative phase component VoutN of the differential output signal Vout on the basis of the current signal Ic2. In the present embodiment, the load resistor 16b converts the current signal Ic2 into the negative phase component VoutN. Specifically, the collector potential of the transistor 15d generated by the current signal Ic2 flowing to the load resistor 16b is output from the terminal Toutn as the negative phase component VoutN.

For example, when a current value of the current signal Ic2 is zero, a voltage level of the negative phase component VoutN becomes the upper limit VlimitH described above. When the current value of the current signal Ic2 is equal to the current value of the direct current

Idc1, the voltage level of the negative phase component VoutN becomes the lower limit VlimitL described above. If the voltage level of the negative phase component VoutN reaches the upper limit VlimitH or the lower limit VlimitL, the negative phase component VoutN is saturated. The positive phase component VoutP and the negative phase component VoutN are complementary signals. For the direct current Idc1 and the resistance values R_{L} and R_{EPB} defined for the linear operation of the positive phase component VoutP, the voltage level of the negative phase component VoutN is higher than the lower limit VlimitL and is lower than the upper limit VlimitH.

The compensation circuit 17 is a circuit that compensates for the operation band of the pre-buffer circuit 10 lowered by the resistors 15e and 15f and the delay adjustment circuit 13. Specifically, the compensation circuit 17 is provided to improve the high frequency characteristics of the pre-buffer circuit 10. The compensation circuit 17 includes an inductor 17a (first inductor) and an inductor 17b (second inductor). The inductors 17a and 17b are configured by, for example, wirings. The inductor 17a is connected in series to the load resistor 16a. That is, one end of the inductor 17a is electrically connected to the other end of the load resistor 16a. The other end of the inductor 17a is electrically connected to the power supply wiring that supplies the power supply voltage VCC. The inductor 17b is connected in series to the load resistor 16b. That is, one end of the inductor 17b is electrically connected to the other end of the load resistor 16b. The other end of the inductor 17b is electrically connected to the power supply wiring that supplies the power supply voltage VCC. The inductances of the inductors 17a and 17b are set so that the operation band (frequency band) of the pre-buffer circuit 10 can be secured. For example, by setting the inductor 17a and the inductor 17b to appropriate values, an upper limit frequency of the operation band can be extended to the high frequency side by peaking, and the operation band can be expanded.

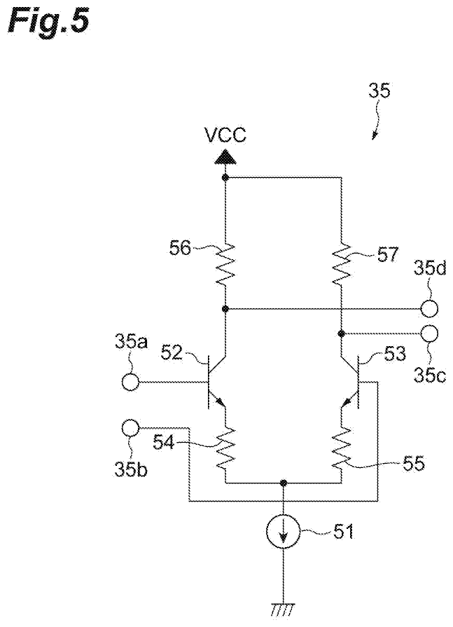

Next, a circuit configuration example of the limiting amplifier 35 will be described. FIG. 5 is a diagram showing an example of a circuit configuration of the limiting amplifier shown in FIG. 3. As shown in FIG. 5, the limiting amplifier 35 includes a current source 51, a transistor 52, a transistor 53, a resistor 54, a resistor 55, a resistor 56, and a resistor 57.

The current source 51 is a circuit that supplies a direct current. A current value of the direct current supplied by the current source 51 is, for example, 0.5 mA to 5 mA. The transistors 52 and 53 are, for example, NPN bipolar transistors. A heterojunction bipolar transistor may be used as the bipolar transistor. A base of the transistor 52 is electrically connected to the non-inverting input node 35a. An emitter of the transistor 52 is electrically connected to the current source 51 via the resistor 54. A collector of the transistor 52 is electrically connected to the power supply wiring for supplying the power supply voltage VCC via the resistor 56 and is electrically connected to the inverting output node 35d. A base of the transistor 53 is electrically connected to the inverting input node 35b. An emitter of the transistor 53 is electrically connected to the current source 51 via the resistor 55. A collector of the transistor 53 is electrically connected to the power supply wiring for supplying the power supply voltage VCC via the resistor 57 and is electrically connected to the non-inverting output node 35c. The transistors 52 and 53 may have the same electrical characteristics, or may be formed by the same transistor structure so as to have the same electrical characteristics. The transistors 52 and 53 may be manufactured by the same semiconductor process on one semiconductor chip.

The resistors 54 and 55 are emitter load resistive elements, and resistance values of the resistors 54 and 55 are, for example, 1 Ω to 50 Ω. The resistance values of the resistors 54 and 55 are set so that the limiting amplifier 35 performs a limiting operation (saturation operation) in the input operation range VRin. The resistors 56 and 57 are load resistive elements, and resistance values of the resistors 56 and 57 are, for example, 50 Ω to 500 Ω. The resistance values of the resistors 56 and 57 may be set to the same values.

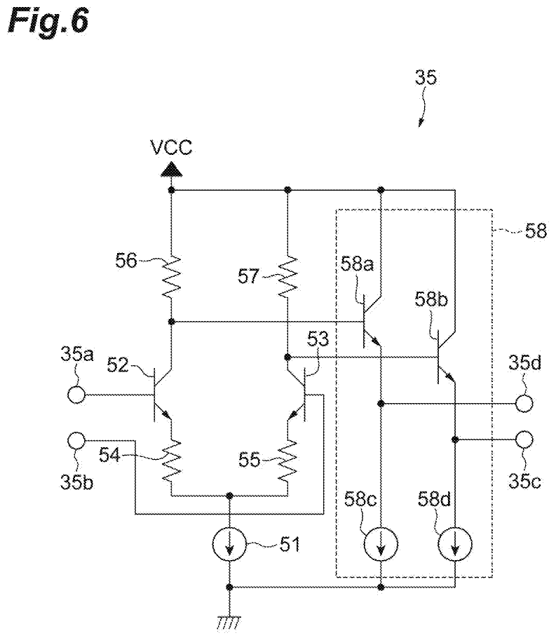

FIG. 6 is a diagram showing another example of the circuit configuration of the limiting amplifier shown in FIG. 3. As shown in FIG. 6, the limiting amplifier 35 may further include an emitter follower 58. The emitter follower 58 includes a transistor 58a, a transistor 58b, a current source 58c, and a current source 58d.

The transistors 58a and 58b are, for example, NPN bipolar transistors. A heterojunction bipolar transistor may be used as the bipolar transistor. A base of the transistor 58a is electrically connected to the collector of the transistor 52. A collector of the transistor 58a is electrically connected to the power supply wiring for supplying the power supply voltage VCC. An emitter of the transistor 58a is electrically connected to the current source 58c and is electrically connected to the inverting output node 35d. A base of the transistor 58b is electrically connected to the collector of the transistor 53. A collector of the transistor 58b is electrically connected to the power supply wiring for supplying the power supply voltage VCC. An emitter of the transistor 58b is electrically connected to the current source 58d and is electrically connected to the non-inverting output node 35c. The current sources 58c and 58d are constant current sources, and a current value of the current supplied by the current sources 58c and 58d is, for example, 0.3 mA to 3 mA. The transistors 58a and 58b may have the same electrical characteristics, or may be formed by the same transistor structure so as to have the same electrical characteristics. The transistors 58a and 58b may be manufactured by the same semiconductor process on one semiconductor chip. The current values of the current sources 58c and 58d may be set to the same values.

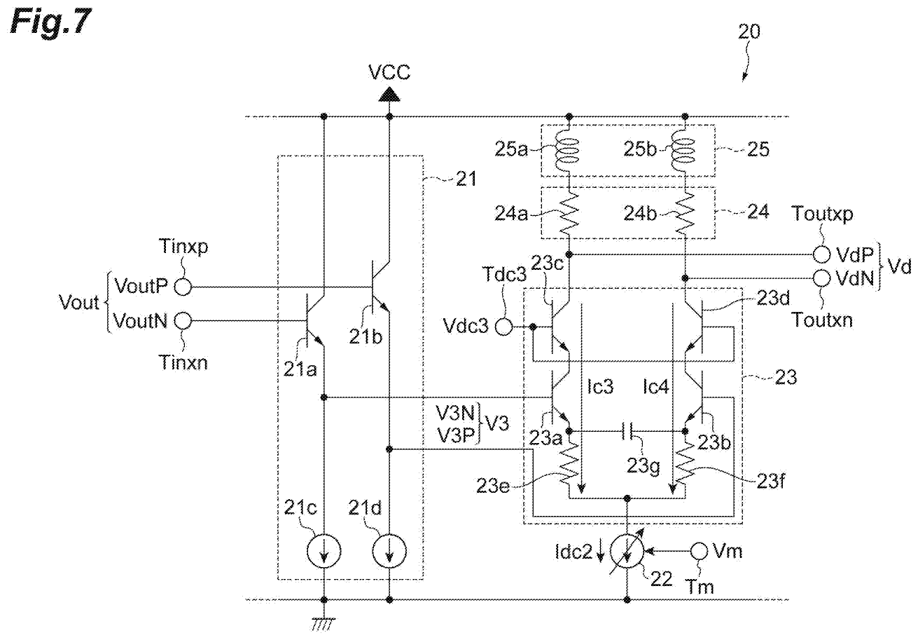

Next, a circuit configuration of the output buffer circuit 20 will be described. FIG. 7 is a diagram showing a circuit configuration of the output buffer circuit shown in FIG. 2. As shown in FIG. 7, the output buffer circuit 20 has a terminal Tinxp, a terminal Tinxn, a terminal Toutxp, a terminal Toutxn, a terminal Tdc3, and a terminal Tin. The terminal Tinxp is electrically connected to the terminal Toutp, and the positive phase component VoutP is input to the terminal Tinxp. The terminal Tinxn is electrically connected to the terminal Toutn, and the negative phase component VoutN is input to the terminal Tinxn. The terminal Toutxp outputs the positive phase component VdP to the optical modulator 3. The terminal Toutxn outputs the negative phase component VdN to the optical modulator 3. However, when the optical modulator 3 is driven with a single phase signal, one of the positive phase signal VdP and the negative phase component VdN may be output to the optical modulator 3, and the other may be electrically connected to a termination resistor. A DC potential Vdc3 (bias voltage) generated in the driving circuit 4 is supplied to the terminal Tdc3. An adjustment signal Vm is supplied to the terminal Tin.

The output buffer circuit 20 includes an emitter follower 21, a current source 22, a differential circuit 23, a load circuit 24, and a compensation circuit 25.

The emitter follower 21 is a circuit that generates a differential signal V3 by lowering the voltage level of the differential output signal Vout. The differential signal V3 has a positive phase component V3P and a negative phase component V3N. The differential signal V3 is a PAM4 signal, and includes four voltage levels (logic levels) of Level-0 to Level-3, similarly to the differential signal V1. The emitter follower 21 includes a transistor 21a, a transistor 21b, a current source 21c, and a current source 21d.

The transistors 21a and 21b are, for example, NPN bipolar transistors. A heterojunction bipolar transistor may be used as the bipolar transistor. A base of the transistor 21a is electrically connected to the terminal Tinxn, and the negative phase component VoutN is input to the base of the transistor 21a. A collector of the transistor 21a is electrically connected to the power supply wiring for supplying the power supply voltage VCC. An emitter of the transistor 21a is electrically connected to one end of the current source 21c. A base of the transistor 21b is electrically connected to the terminal Tinxp, and the positive phase component VoutP is input to the base of the transistor 21b. A collector of the transistor 21b is electrically connected to the power supply wiring for supplying the power supply voltage VCC. An emitter of the transistor 21b is electrically connected to one end of the current source 21d. The current source 21c is a constant current source, and the other end of the current source 21c is connected to the ground potential. The current source 21d is a constant current source, and the other end of the current source 21d is connected to the ground potential.

The transistor 21a and the current source 21c configure an emitter follower unit. This emitter follower unit receives the negative phase component VoutN, lowers the voltage level of the negative phase component VoutN, and outputs the negative phase component VoutN whose voltage level has been lowered to the differential circuit 23 as the negative phase component V3N. The transistor 21b and the current source 21d configure an emitter follower unit. This emitter follower unit receives the positive phase component VoutP, lowers the voltage level of the positive phase component VoutP, and outputs the positive phase component VoutP whose voltage level has been lowered to the differential circuit 23 as the positive phase component V3P.

The current source 22 is a variable current source that supplies the direct current Idc2. The current value of the direct current Idc2 is set by the adjustment signal Vm supplied to the terminal Tin. The current source 22 supplies the direct current Idc2 to the differential circuit 23.

The differential circuit 23 is a circuit that divides the direct current Idc2 into a current signal Ic3 and a current signal Ic4, according to the difference between the positive phase component V3P and the negative phase component V3N. That is, the differential circuit 23 divides the direct current Idc2 into two current signals according to the difference between the positive phase component V3P and the negative phase component V3N, and generates a differential current signal (the current signal Ic3 and the current signal Ic4). The differential circuit 23 includes a transistor 23a, a transistor 23b, a transistor 23c, a transistor 23d, a resistor 23e, a resistor 23f, and a capacitor 23g.

The transistors 23a to 23d are, for example, NPN bipolar transistors. A heterojunction bipolar transistor may be used as the bipolar transistor. The transistors 23a and 23b are transistors for switching. Since the transistors 23a and 23b are used as a pair, the transistors 23a and 23b may have the same electrical characteristics.

Therefore, the transistors 23a and 23b may have the same structure formed of the same material. A base of the transistor 23a is electrically connected to the emitter of the transistor 21a, and the negative phase component V3N is input to the base of the transistor 23a. An emitter of the transistor 23a is electrically connected to the current source 22 via the resistor 23e. A collector of the transistor 23a is electrically connected to an emitter of the transistor 23c, and outputs the current signal Ic3. A base of the transistor 23b is electrically connected to the emitter of the transistor 21b, and the positive phase component V3P is input to the base of the transistor 23b. An emitter of the transistor 23b is electrically connected to the current source 22 via the resistor 23f. A collector of the transistor 23b is electrically connected to an emitter of the transistor 23d and outputs the current signal Ic4.

The transistors 23c and 23d are cascode transistors. A base of the transistor 23c is electrically connected to the terminal Tdc3, and the DC potential Vdc3 is applied to the base of the transistor 23c. A collector of the transistor 23c is electrically connected to the load circuit 24 and is electrically connected to the terminal Toutxp. A base of the transistor 23d is electrically connected to the terminal Tdc3, and the DC potential Vdc3 is applied to the base of the transistor 23d. A collector of the transistor 23d is electrically connected to the load circuit 24 and is electrically connected to the terminal Toutxn. The transistors 23c and 23d speed up the switching operation of the transistors 23a and 23b by maintaining the collector potential of the transistors 23a and 23b at a constant value according to the DC potential Vdc3. The transistors 23c and 23d may have the same electrical characteristics. Therefore, the transistors 23c and 23d may have the same structure formed of the same material.

The resistors 23e and 23f are resistive elements for a linear operation. The transistor 23a operates in a region where the emitter current of the transistor 23a is not turned off by the resistor 23e. Similarly, the transistor 23b operates in a region where the emitter current of the transistor 23b is not turned off by the resistor 23f. In other words, if the resistance values of the resistor 23e and the resistor 23f are increased, the differential voltage gain when the differential signal V3 is amplified by the differential circuit 23 to generate the driving signal Vd decreases, and a linear amplification region for the differential signal V3 becomes wider. The resistance value of the resistor 23e may be the same as the resistance value of the resistor 23f. In the differential circuit 23, the current signal Ic3 flows to the transistor 23c, the transistor 23a, and the resistor 23e. The current signal Ic4 flows to the transistor 23d, the transistor 23b, and the resistor 23f. The capacitor 23g is a capacitive element for improving the high frequency characteristics of the output buffer circuit 20. For example, the capacitor 23g is configured by forming parallel plates with two wiring layers on a semiconductor chip. One end of the capacitor 23g is electrically connected to the emitter of the transistor 23a, and the other end of the capacitor 23g is electrically connected to the emitter of the transistor 23b.

The load circuit 24 is a circuit that converts the differential current signal (the current signal Ic3 and the current signal Ic4) into the driving signal Vd. The load circuit 24 includes a load resistor 24a and a load resistor 24b. One end of the load resistor 24a is electrically connected to the collector of the transistor 23c. The other end of the load resistor 24a is electrically connected to the compensation circuit 25. The load resistor 24a generates the positive phase component VdP of the driving signal Vd on the basis of the current signal Ic3. In the present embodiment, the load resistor 24a converts the current signal Ic3 into the positive phase component VdP. Specifically, the collector potential of the transistor 23c generated by the current signal Ic3 flowing to the load resistor 24a is output from the terminal Toutxp as the positive phase component VdP.

One end of the load resistor 24b is electrically connected to the collector of the transistor 23d. The other end of the load resistor 24b is electrically connected to the compensation circuit 25. The load resistor 24b generates the negative phase component VdN of the driving signal Vd on the basis of the current signal Ic4. In the present embodiment, the load resistor 24b converts the current signal Ic4 into the negative phase component VdN. Specifically, the collector potential of the transistor 23d generated by the current signal Ic4 flowing to the load resistor 24b is output from the terminal Toutxn as the negative phase component VdN.

The compensation circuit 25 is a circuit that compensates for the operation band of the output buffer circuit 20 lowered by the resistors 23e and 23f. Specifically, the compensation circuit 25 is provided to improve the high frequency characteristics of the output buffer circuit 20 by increasing the differential voltage gain in a specific high frequency region by peaking. The compensation circuit 25 includes an inductor 25a and an inductor 25b. For example, the inductors 25a and 25b are configured by wirings on a semiconductor chip. The inductor 25a is connected in series to the load resistor 24a. That is, one end of the inductor 25a is electrically connected to the other end of the load resistor 24a. The other end of the inductor 25a is electrically connected to the power supply wiring for supplying the power supply voltage VCC. The inductor 25b is connected in series to the load resistor 24b. That is, one end of the inductor 25b is electrically connected to the other end of the load resistor 24b. The other end of the inductor 25b is electrically connected to the power supply wiring for supplying the power supply voltage VCC. The inductances of the inductors 25a and 25b are set so that the operation band (frequency band) of the output buffer circuit 20 can be secured.

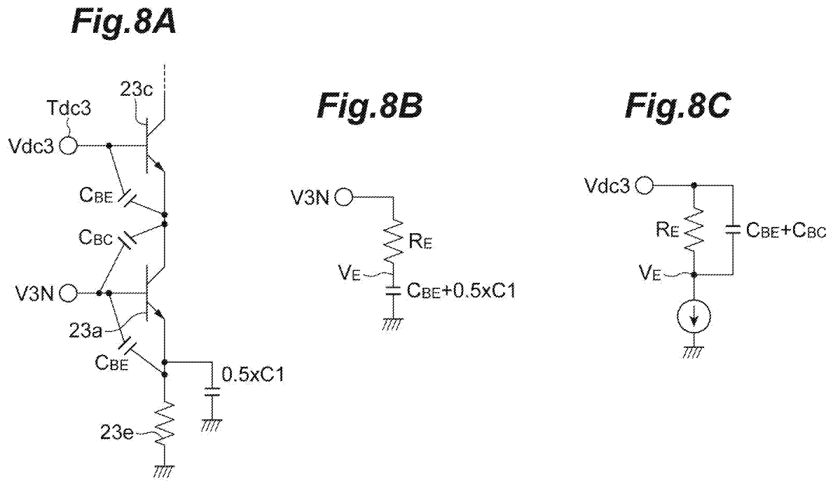

Next, main time constants of the output buffer circuit 20 will be described. FIG. 8A is an equivalent circuit diagram showing a circuit configuration of a single phase side of the output buffer circuit shown in FIG. 7. FIG. 8B is a diagram illustrating a time constant of the transistor for switching. FIG. 8C is a diagram illustrating a time constant of the cascode transistor. Since the differential circuit configuration of the output buffer circuit 20 is symmetrical, FIG. 8A shows the circuit configuration of the single phase side. An emitter potential V_{E} has a time constant τ_{E}. The time constant τ_{E} is a time constant of a low-pass filter configured by an emitter resistor R_{E} and an emitter capacitor C_{E}, and is represented by Formula (1). A transfer function T(s) is represented by Formula (2) using the time constant τ_{E}.

$$\begin{matrix}[ Formula 1 ] & \\ {τ}_{E} = {R}_{E} {C}_{E} & ( 1 ) \\ [ Formula 2 ] & \\ T ( s ) = \frac{1}{s {τ}_{E} + 1} & ( 2 )\end{matrix}$$

As shown in FIG. 8B, the emitter capacitance C_{E} of the transistors 23a and 23b is represented by Formula (3) using the capacitance C1 of the capacitor 23g.

[Formula 3]

C_{E}=C_{BE}+0.5×C1 (3)

As shown in FIG. 8C, the emitter capacitance C_{E} of the transistors 23c and 23d is represented by Formula (4).

[Formula 4]

C_{E}=C_{BE}+C_{BC} (4)

Here, in the output buffer circuit 20, the emitter current I_{E} of the transistors 23a to 23d is represented by Formula (5) using the saturation current I_{S}, the base-emitter voltage V_{BE}, and the thermal voltage V_{F}.

$$\begin{matrix}[ Formula 5 ] & \\ {I}_{E} = {I}_{S} Exp ( \frac{{V}_{BE}}{{V}_{F}} ) & ( 5 )\end{matrix}$$

The thermal voltage V_{F} is represented by Formula (6) using the Boltzmann constant k, the absolute temperature T, and the electron charge q.

$$\begin{matrix}[ Formula 6 ] & \\ {V}_{F} = \frac{kT}{q} & ( 6 )\end{matrix}$$

By modifying Formula (5), the base-emitter voltage V_{BE} is represented by Formula (7).

$$\begin{matrix}[ Formula 7 ] & \\ {V}_{BE} = {V}_{F} ln ( \frac{{I}_{E}}{{I}_{S}} ) & ( 7 )\end{matrix}$$

Since the (intrinsic) emitter resistance R_{E} of the transistors 23a to 23d is the differential resistance of the diode units of the transistors 23a to 23d, the emitter resistance R_{E} is represented by Formula (8).

$$\begin{matrix}[ Formula 8 ] & \\ {R}_{E} = \frac{{dV}_{BE}}{{dI}_{E}} = {V}_{F} \frac{{I}_{S}}{{I}_{E}} & ( 8 )\end{matrix}$$

According to Formula (8), the emitter resistance R_{E} of the transistors 23a to 23d is inversely proportional to the emitter current I_{E}. For this reason, if the emitter current I_{E} decreases, the emitter resistance R_{E} increases. Therefore, the time constant τT_{E} of the transistors 23a to 23d increases as the emitter current I_{E} decreases.

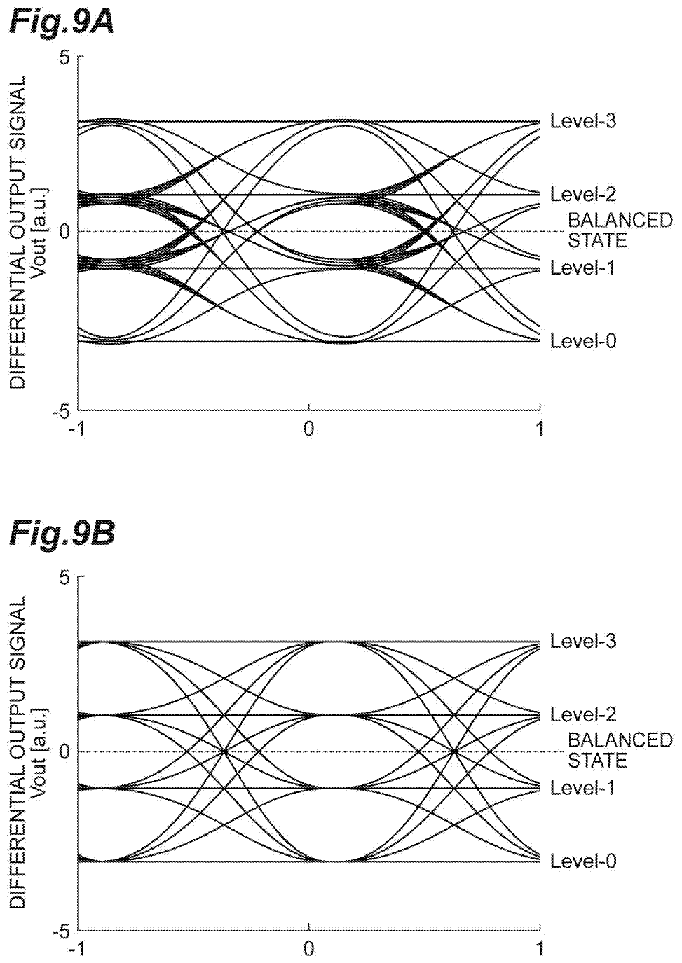

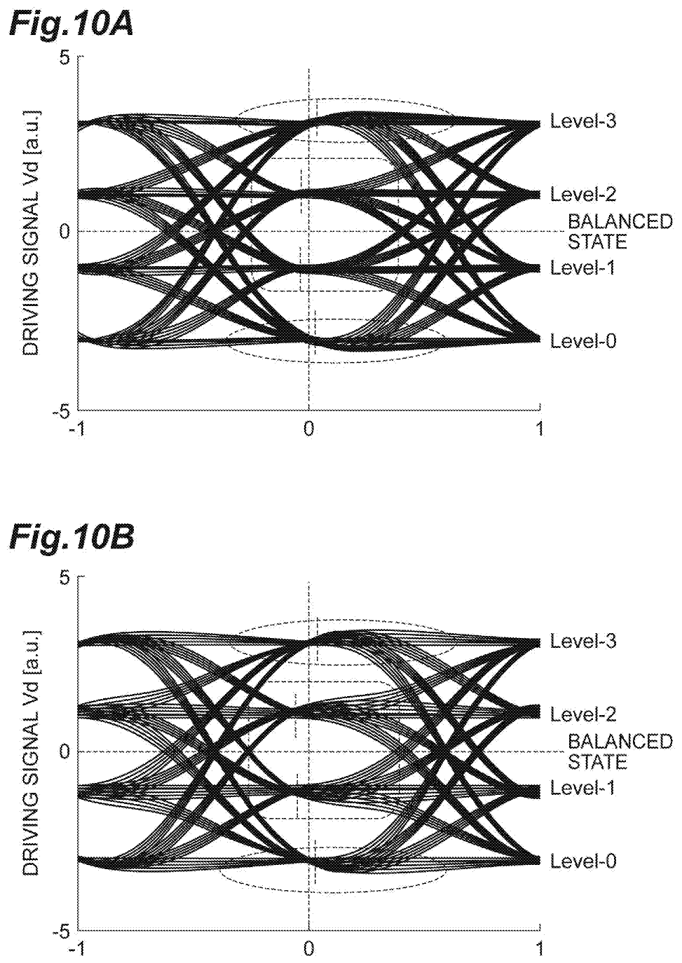

Next, functions and effects of the driving circuit 4 will be described while the driving circuit 4 is compared with a driving circuit for an optical modulator according to a comparative example. FIG. 9A is a diagram showing an example of a differential output signal output from the pre-buffer circuit shown in FIG. 2. FIG. 9B is a diagram showing an example of a differential output signal output from a pre-buffer circuit according to the comparative example. FIG. 10A is a diagram showing an example of a driving signal output from the driving circuit shown in FIG. 2. FIG. 10B is a diagram showing an example of a driving signal output from the driving circuit according to the comparative example.

The driving circuit according to the comparative example is mainly different from the driving circuit 4 in that the pre-buffer circuit does not include the delay adjustment circuit 13. That is, in the pre-buffer circuit according to the comparative example, the differential signal V1 generated by the emitter follower 12 is supplied to the differential circuit 15 as the differential signal V2. In the driving circuit 4, in order to compensate for the decrease in the band due to the addition of the delay adjustment circuit 13, the inductances of the inductors 17a and 17b of the pre-buffer circuit 10 are set to 1.4 times the inductances of the inductors 17a and 17b of the pre-buffer circuit according to the comparative example. An output buffer circuit included in the driving circuit according to the comparative example has the same circuit configuration as the output buffer circuit 20.

In the output buffer circuit 20, when the differential signal V3 is in a balanced state, the current signal Ic3 and the current signal Ic4 are equal to each other, and each of the current signals Ic3 and Ic4 is half of the direct current Idc2. That is, Ic3=Ic4=0.5×Idc2 is satisfied. When the voltage level of the positive phase component V3P is around Level-3, that is, when the voltage level of the negative phase component V3N is around Level-0, the current signal Ic3 decreases to about 0.1 times the direct current Idc2. On the other hand, when the voltage level of the positive phase component V3P is around Level-0, that is, when the voltage level of the negative phase component V3N is around Level-3, the current signal Ic4 decreases to about 0.1 times the direct current Idc2.

As described above, when the voltage level of the positive phase component V3P is around Level-3 and the voltage level of the negative phase component V3N is around Level-0, the emitter current I_{E} of the transistors 23a and 23c decreases, so that the emitter resistance R_{E} increases, and the time constant τ_{E} also increases. On the other hand, when the voltage level of the positive phase component V3P is around Level-0 and the voltage level of the negative phase component V3N is around Level-3, the emitter current I_{E} of the transistors 23b and 23d decreases, so that the emitter resistance R_{E} increases, and the time constant τ_{E} also increases.

In the pre-buffer circuit of the driving circuit according to the comparative example, since the frequency characteristics do not depend on the amplitude (voltage level) of the differential output signal Vout, as shown in FIG. 9B, timing (sticking timing) at which the voltage level of the positive phase component VoutP (negative phase component VoutN) reaches each of Level-0 to Level-3 is substantially the same. As described above, in the output buffer circuit, the time constant τ_{E} when the voltage level of the positive phase component V3P (negative phase component V3N) is Level-0 or Level-3 is larger than the time constant τ_{E} when the voltage level of the positive phase component V3P (negative phase component V3l N) is Level-1 or Level-2. For this reason, as shown in FIG. 10B, a waveform of the driving signal Vd output from the output buffer circuit 20 is distorted.

Specifically, the timing (sticking timing) at which the voltage level of the positive phase component VdP (negative phase component VdN) of the driving signal Vd reaches Level-0 or Level-3 is later than the timing (sticking timing) at which the voltage level of the positive phase component VdP (negative phase component VdN) of the driving signal Vd reaches Level-1 or Level-2. An amount of overshoot when the voltage level of the positive phase component VdP (negative phase component VdN) is Level-0 or Level-3 is smaller than an amount of overshoot when the voltage level of the positive phase component VdP (negative phase component VdN) is Level-1 or Level-2.

The level determination of an eye pattern of the PAM4 signal is often performed at one determination timing on the time axis. However, timing at which a variation in a voltage direction of the driving signal Vd is minimized when the voltage level of the positive phase component VdP is Level-1 or Level-2 is different from timing at which a variation in the voltage direction of the driving signal Vd is minimized when the voltage level of the positive phase component VdP is Level-0 or Level-3. For this reason, if the level determination is performed at one determination timing, the variation in the voltage direction is not minimized at the voltage levels of Level-1 and Level-2 or Level-0 and Level-3, so that an SN ratio may be deteriorated, and inter-symbol interference (ISI) may increase. In other words, the S/N ratio may be deteriorated due to waveform distortion rather than random noise.

On the other hand, in the driving circuit 4, the pre-buffer circuit 10 includes the delay adjustment circuit 13. A time constant τ_{filter} of the delay adjustment circuit 13 is represented by Formula (9) using an output resistance value R_{EF} of the emitter follower 12, a resistance value R_{f1} of the resistors 31 and 32, an input capacitance C_{filterin} of an amplifier including the limiting amplifier 35 and the capacitors 33 and 34, and an input capacitance C_{diffin} of the differential circuit 15. The transfer function T(s) is represented by Formula (10) using the time constant τ_{filter}.

$$\begin{matrix}[ Formula 9 ] & \\ {τ}_{filter} = ( {R}_{EF} + {R}_{f 1} ) ( {C}_{filterin} + {C}_{diffin} ) & ( 9 ) \\ [ Formula 10 ] & \\ T ( s ) = \frac{1}{s {τ}_{filter} + 1} & ( 10 )\end{matrix}$$

The input capacitance C_{filterin} is represented by Formula (11) using a capacitance C_{f1} of the capacitors 33 and 34, an input capacitance Cₐₘₚᵢₙ of the limiting amplifier 35, and a gain Gₐₘₚ of the limiting amplifier 35.

[Formula 11]

C_{filterin}=Cₐₘₚᵢₙ+(Gₐₘₚ+1)C_{f1} (11)

By substituting Formula (11) for Formula (9), Formula (12) is obtained. That is, when the voltage level of the differential signal V1 is in the input operation range VRin, the limiting amplifier 35 operates in a non-saturated region, so that a time constant τ_{filter_inner} in that case is represented by Formula (12).

[Formula 12]

τ_{filter_inner}=(R_{EF}+R_{f1}) (Cₐₘₚᵢₙ+(Gₐₘₚ+1)C_{f1}+C _{diffin}) (12)

On the other hand, when the voltage level of the differential signal V1 is outside the input operation range VRin, the limiting amplifier 35 operates in a saturated region, so that the gain Gₐₘₚ is 0. A time constant τ_{filter_outer} in that case is represented by Formula (13).

[Formula 13]

τ_{filter_outer}=(R_{EF}+R_{f1}) (Cₐₘₚᵢₙ+C_{f1}+C_{diffin}) (13)

For example, when the input capacitance Cₐₘₚᵢₙ and the input capacitance C_{diffin} are 70 fF, the capacitance C_{f1} is 15 fF, and the gain Gₐₘₚ is 10, the total capacitance value of the time constant τ_{filter_inner} is 305 fF, and the total capacitance value of the time constant τ_{filter_outer} is 155 fF. Therefore, the time constant τ_{filter_outer} is about 50% of the time constant τ_{filter_inner}.

Since the time constant τ_{filter_inner} is larger than the time constant τ_{filter_outer}, an amount of delay given to the differential signal V1 when the voltage level of the differential signal V1 is Level-1 or Level-2 is larger than an amount of delay given to the differential signal V1 when the voltage level of the differential signal V1 is Level-0 or Level-3. As a result, in the differential output signal Vout output from the pre-buffer circuit 10, as shown in FIG. 9A, the timing at which the voltage level of the positive phase component VoutP (negative phase component VoutN) of the differential output signal Vout reaches Level-1 or Level-2 is later than the timing at which the voltage level of the positive phase component VoutP (negative phase component VoutN) of the differential output signal Vout reaches Level-0 or Level-3.

As described above, the time constant τ_{E} when the voltage level of the differential input signal Vin (differential output signal Vout) is

Level-0 or Level-3 is larger than the time constant τ_{E} when the voltage level of the differential input signal Vin (differential output signal Vout) is Level-1 or Level-2. However, since the time constant τ_{filter_outer} is smaller than the time constant τ_{filter_inner}, in the driving signal Vd, the difference in the delay amount for each voltage level decreases. Therefore, the difference in the delay amount of the sticking timing according to the voltage level of the driving signal Vd generated in the output buffer circuit 20 is reduced.

As shown in FIG. 10A, since the timing (sticking timing) at which the voltage level of the positive phase component VdP (negative phase component VdN) reaches each of Level-0 to Level-3 is substantially the same, the distortion generated in the waveform of the driving signal Vd is reduced. The difference between the amount of overshoot when the voltage level of the positive phase component VdP (negative phase component VdN) is Level-1 or Level-2 and the amount of overshoot when the voltage level of the positive phase component VdP (negative phase component VdN) is Level-0 or Level-3 decreases. As a result, even if the level determination is performed at one determination timing, it is possible to suppress the deterioration of the SN ratio.

The SN ratio of the waveform of the driving signal Vd shown in FIG. 10B is 28.9 dB, and the SN ratio of the waveform of the driving signal Vd shown in FIG. 10A is 32.0 dB. In other words, the SN ratio is improved by 3.1 dB.

As described above, in the driving circuit 4, the differential signal V1 is generated by lowering the voltage level of the differential input signal Vin, and the differential signal V2 is generated by delaying the differential signal V1 by the delay amount according to the voltage level of the differential signal V1. According to the difference between the positive phase component V2P of the differential signal V2 and the negative phase component V2N of the differential signal V2, the direct current Idc1 supplied by the current source 14 is divided into the current signal Ic1 and the current signal Ic2, the positive phase component VoutP of the differential output signal Vout is generated on the basis of the current signal Ic1, and the negative phase component VoutN of the differential output signal Vout is generated on the basis of the current signal Ic2. Here, when the difference in the voltage level between the positive phase component V2P and the negative phase component V2N increases, the difference is generated in the division ratio between the current signal Ic1 and the current signal Ic2, and the magnitude of one of the current signals decreases. Further, when the magnitude of the current signal decreases, the time constant τ_{E} increases, so that the delay amount of the differential output signal Vout increases. In other words, the delay amount of the differential output signal Vout when the voltage level of the differential signal V1 is Level-0 or Level-3 is larger than the delay amount of the differential output signal Vout when the voltage level of the differential signal V1 is Level-1 or Level-2. The same delay can occur even in the output buffer circuit 20.

The limiting amplifier 35 operates in a non-saturated region when the voltage level of the differential signal V1 is in the input operation range VRin, and operates in a saturated region when the voltage level of the differential signal V1 is outside the input operation range VRin. As described above, when the limiting amplifier 35 connected in negative feedback via the capacitors 33 and 34 operates in a non-saturated region, the capacitance of the delay adjustment circuit 13 is multiplied by the gain of the limiting amplifier 35. For this reason, when the voltage level of the differential signal V1 is Level-1 or Level-2, the capacitance of the delay adjustment circuit 13 is multiplied by the gain of the limiting amplifier 35, so that the delay amount added to the differential signal V1 by the delay adjustment circuit 13 increases. On the other hand, when the limiting amplifier 35 operates in a saturated region, the gain of the limiting amplifier 35 is not reflected in the capacitance of the delay adjustment circuit 13. For this reason, when the voltage level of the differential signal V1 is Level-0 or Level-3, the capacitance of the delay adjustment circuit 13 is not multiplied, so that the delay amount added to the differential signal V1 by the delay adjustment circuit 13 is small. Therefore, when the voltage level of the differential input signal Vin (differential output signal Vout) is Level-1 or Level-2 and when the voltage level is Level-0 or Level-3, the sum of the delay amount by the time constant τ_{E} of the transistor in the differential circuits 15 and 23 and the delay amount added by the delay adjustment circuit 13 is substantially the same. As a result, the difference in the delay amount due to the voltage level of the differential input signal Vin (differential output signal Vout) is reduced, so that waveform distortion can be reduced, and the SN ratio (waveform quality) can be improved.

Level-0 and Level-3 are symmetric around an average voltage (balanced state) of the differential signal V1. For this reason, the timing at which the voltage level of the positive phase component VdP reaches Level-0 is substantially matched with the timing at which the voltage level of the positive phase component VdP reaches Level-3. That is, timing at which a variation in a voltage direction of the driving signal Vd is minimized when the voltage level of the positive phase component VdP is Level-0 is substantially matched with timing at which a variation in the voltage direction of the driving signal Vd is minimized when the voltage level of the positive phase component VdP is Level-3. Similarly, Level-1 and Level-2 are symmetric around the average voltage (balanced state) of the differential signal V1. For this reason, timing at which the voltage level of the positive phase component VdP reaches Level-1 is substantially matched with timing at which the voltage level of the positive phase component VdP reaches Level-2. That is, timing at which a variation in a voltage direction of the driving signal Vd is minimized when the voltage level of the positive phase component VdP is Level-1 is substantially matched with timing at which a variation in the voltage direction of the driving signal Vd is minimized when the voltage level of the positive phase component VdP is Level-2. Therefore, the difference in the delay amount due to the voltage level of the differential input signal Vin (differential output signal Vout) is further reduced, so that waveform distortion can be further reduced.

In the differential circuit 15, since the DC potential Vdc2 is applied to the base of the transistor 15c, a variation in the emitter potential of the transistor 15c is suppressed. As a result, a variation in the collector potential of the transistor 15a is suppressed. A stray capacitance is generated between the base and the collector of the transistor 15a, and the stray capacitance changes depending on the collector potential of the transistor 15a. However, since the variation in the collector potential of the transistor 15a is suppressed, the potential variation is suppressed from being transmitted to the base of the transistor 15a via the stray capacitance. Similarly, since the DC potential Vdc2 is applied to the base of the transistor 15d, the variation in the emitter potential of the transistor 15d is suppressed, and the variation in the collector potential of the transistor 15b is suppressed. As a result, since the switching operation of the transistors 15a and 15b is stabilized, the differential output signal Vout can be speeded up.

The pre-buffer circuit 10 includes the inductor 17a connected in series to the load resistor 16a and the inductor 17b connected in series to the load resistor 16b. For this reason, by adjusting the inductances of the inductors 17a and 17b, it is possible to compensate for the reduction in the band due to the delay adjustment circuit 13 by increasing the gain in a specific high frequency region.

The driving circuit for the optical modulator according to the present disclosure is not limited to the above embodiment.

For example, each signal such as the differential input signal Vin, the differential output signal Vout, the driving signal Vd, and the optical signal Pout may have four or more logic levels and may be, for example, a signal such as PAM8 and PAM16. In that case, a limiting amplifier whose input operation range is set to be wider or narrower than that of the limiting amplifier 35 may be prepared and connected in parallel with the limiting amplifier 35.

The pre-buffer circuit 10 may not include the input termination circuit 11, may not include the emitter follower 12, and may not include the compensation circuit 17.

The differential circuit 15 may not include the cascode transistors (transistors 15c and 15d). For example, in that case, the collector of the transistor 15a is electrically connected to the load resistor 16a and the terminal ToutP, and the collector of the transistor 15b is electrically connected to the load resistor 16b and the terminal ToutN. Similarly, the differential circuit 23 may not include the cascode transistors (transistors 23c and 23d).

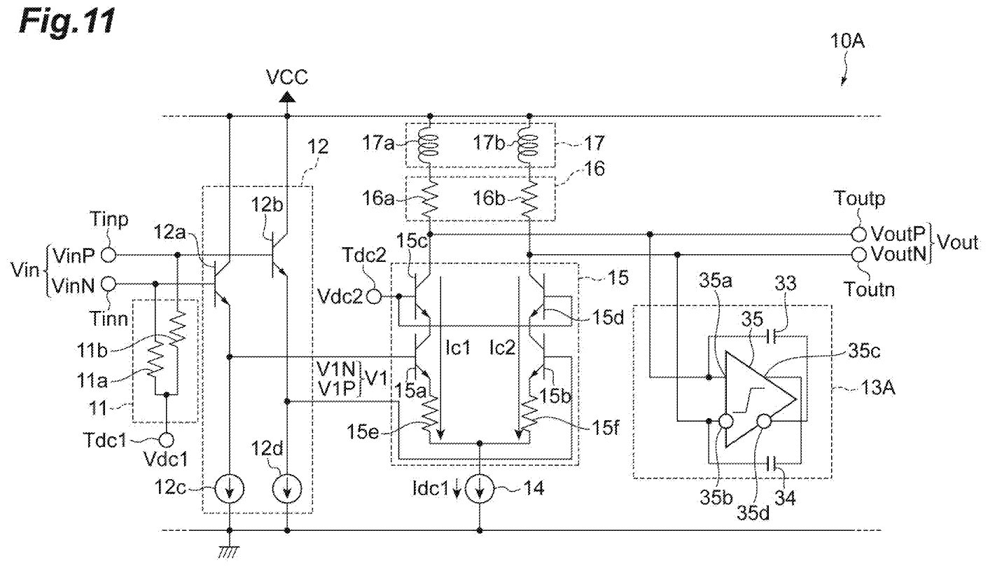

FIG. 11 is a diagram showing a modification of the circuit configuration of the pre-buffer circuit shown in FIG. 2. As shown in FIG. 11, a pre-buffer circuit 10A (first differential amplifier) is mainly different from the pre-buffer circuit 10 in that a delay adjustment circuit 13A is provided instead of the delay adjustment circuit 13. The delay adjustment circuit 13A is mainly different from the delay adjustment circuit 13 in that the delay adjustment circuit 13A does not include the resistors 31 and 32 and in a connection location.

The delay adjustment circuit 13A is connected between an output unit of the differential circuit 15 and the output buffer circuit 20. Specifically, the non-inverting input node 35a of the limiting amplifier 35 is electrically connected between the collector of the transistor 15c and the terminal Toutp. In other words, the non-inverting input node 35a is electrically connected between one end of the load resistor 16a and the output buffer circuit 20. The inverting input node 35b of the limiting amplifier 35 is electrically connected between the collector of the transistor 15d and the terminal Toutn. In other words, the inverting input node 35b is electrically connected between one end of the load resistor 16b and the output buffer circuit 20.

The delay adjustment circuit 13A is a circuit that delays the differential output signal Vout by a delay amount according to the voltage level of the differential output signal Vout instead of the differential signal V1. The differential output signal Vout is, for example, a PAM4 signal, and includes four voltage levels (logic levels) of Level-0 to Level-3 that increase in this order, similarly to the differential signal V1. Level-0 and Level-3 are symmetric around the average voltage (balanced state) of the differential output signal Vout. Level-1 and Level-2 are symmetric around the average voltage (balanced state) of the differential output signal Vout. For example, when the voltages of Level-0 to Level-3 are set as V_0 to V_3, respectively, and the average voltage is set as Vb, V_3−Vb=Vb−V_0 and V_2−Vb=Vb−V_1 are obtained in the above symmetry.

The limiting amplifier 35 operates in a non-saturated region (linear amplification) when the voltage level of the differential output signal Vout is in the input operation range VRin, and operates in a saturated region when the voltage level of the differential output signal Vout is outside the input operation range VRin. In the delay adjustment circuit 13A, the voltage VL in the input operation range VRin is larger than Level-0 of the differential output signal Vout and is smaller than Level-1 of the differential output signal Vout. The voltage VH in the input operation range VRin is larger than Level-2 of the differential output signal Vout and is smaller than Level-3 of the differential output signal Vout. The input operation range VRin is set at a predetermined ratio with respect to the input amplitude of the differential output signal Vout, for example. For example, the input operation range VRin is set to 30% to 70% of the input amplitude of the differential output signal Vout with the average voltage of the differential output signal Vout as the center.

In the pre-buffer circuit 10A, the delay adjustment circuit 13A, the load circuit 16, and the compensation circuit 17 configure a filter.

In the pre-buffer circuit 10A, the delay adjustment circuit 13 is not provided between the emitter follower 12 and the differential circuit 15. For this reason, the base of the transistor 15a is electrically connected to the emitter of the transistor 12a. The negative phase component V1N is input to the base of the transistor 15a. Similarly, the base of the transistor 15b is electrically connected to the emitter of the transistor 12b. The positive phase component V1P is input to the base of the transistor 15b. That is, in the driving circuit 4 of the modification, the direct current Idc1 supplied by the current source 14 is divided into the current signal Ic1 and the current signal Ic2, according to the difference between the positive phase component V1P of the differential signal V1 (differential input signal) and the negative phase component V1N of the differential signal V1. The positive phase component VoutP of the differential output signal Vout is generated on the basis of the current signal Ic1, and the negative phase component VoutN of the differential output signal Vout is generated on the basis of the current signal Ic2.

Here, when the difference between the positive phase component V1P and the negative phase component V1N increases, the difference is generated in the division ratio between the current signal Ic1 and the current signal Ic2, and the magnitude of one of the current signals decreases. Further, when the magnitude of the current signal decreases, the time constant τ_{E} increases, so that the delay amount of the differential output signal Vout increases. In other words, the delay amount of the differential output signal Vout when the voltage level of the differential output signal Vout is Level-0 or Level-3 is larger than the delay amount of the differential output signal Vout when the voltage level of the differential output signal Vout is Level-1 or Level-2. The same delay can occur even in the output buffer circuit 20.

In the driving circuit 4 according to the modification, the non-inverting input node 35a of the limiting amplifier 35 is electrically connected between the load resistor 16a and the output buffer circuit 20 (terminal Toutp), and the inverting input node 35b of the limiting amplifier 35 is electrically connected between the load resistor 16b and the output buffer circuit 20 (terminal Toutn). Further, the non-inverting input node 35a and the inverting output node 35d of the limiting amplifier 35 are electrically connected via the capacitor 33, and the inverting input node 35b and the non-inverting output node 35c of the limiting amplifier 35 are electrically connected via the capacitor 34.

The limiting amplifier 35 operates in a non-saturated region when the voltage level of the differential output signal Vout is in the input operation range VRin, and operates in a saturated region when the voltage level of the differential output signal Vout is outside the input operation range VRin. As described above, when the limiting amplifier 35 connected in negative feedback via the capacitors 33 and 34 operates in a non-saturated region, the capacitance of the delay adjustment circuit 13A is multiplied by the gain of the limiting amplifier 35. For this reason, when the voltage level of the differential output signal Vout is Level-1 or Level-2, the capacitance of the delay adjustment circuit 13A is multiplied by the gain of the limiting amplifier 35, so that the delay amount added to the differential output signal Vout by the delay adjustment circuit 13A increases. On the other hand, when the limiting amplifier 35 operates in a saturated region, the gain of the limiting amplifier 35 is not reflected in the capacitance of the delay adjustment circuit 13A. For this reason, when the voltage level of the differential output signal Vout is Level-0 or Level-3, the capacitance of the delay adjustment circuit 13A is not increased, so that the delay amount added to the differential output signal Vout by the delay adjustment circuit 13A is small. As a result, the difference in the delay amount due to the voltage level of the differential output signal Vout is reduced, so that waveform distortion can be reduced, and the SN ratio (waveform quality) can be improved.

As described above, even in the driving circuit 4 according to the modification, the same effects as the driving circuit 4 according to the embodiment can be obtained. In the driving circuit 4 according to the modification, since the resistors 31 and 32 can be omitted, the driving circuit 4 can be miniaturized. Since the delay adjustment circuit 13A is added to the output unit of the pre-buffer circuit 10A, the delay adjustment circuit 13A can be added relatively easily to a pre-buffer circuit not including the delay adjustment circuit 13A without greatly changing the arrangement and the wiring. For example, the delay adjustment circuit 13A may be electrically connected between the terminals Toutp and Toutn and the output buffer circuit 20.

What is claimed is:

1. A driving circuit to generate a driving signal for an optical modulator in response to a differential input signal having a positive phase component and a negative phase component, the driving circuit comprising:
a first differential amplifier configured to generate a differential output signal in response to a difference between the positive phase component and the negative phase component of the differential input signal, the differential output signal having a positive phase component and a negative phase component; and
a second differential amplifier configure to generate the driving signal in response to the differential output signal,
wherein the first differential amplifier comprises:
an emitter follower configured to generate a first differential signal by lowering voltage level of the differential input signal, the first differential signal having a positive phase component and a negative phase component;
a delay adjustment circuit configured to generate a second differential signal by delaying the first differential signal in response to instantaneous voltage level of the first differential signal, the second differential signal having a positive phase component and a negative phase component;
a current source configured to supply a source current;
a differential circuit configured to divide the source current into a first current and a second current, the first current and the second current varying complementarily in response to a difference between the positive phase component of the second differential signal and the negative phase component of the second differential signal;
a first load resistor configured to generate the positive phase component of the differential output signal based on the first current; and
a second load resistor configured to generate the negative phase component of the differential output signal based on the second current,
wherein the delay adjustment circuit comprises:
a positive phase input node configured to receive the positive phase component of the first differential signal;
a negative phase input node configured to receive the negative phase component of the first differential signal;
a positive phase output node configured to output the positive phase component of the second differential signal;
a negative phase output node configured to output the negative phase component of the second differential signal;
a first resistor electrically connected between the positive phase input node and the positive phase output node;
a second resistor electrically connected between the negative phase input node and the negative phase output node;
a first capacitor;
a second capacitor; and
a third differential amplifier having a non-inverting input node, an inverting input node, a non-inverting output node, and an inverting output node, the non-inverting input node being electrically connected between the second resistor and the negative phase output node, the inverting input node being electrically connected between the first resistor and the positive phase output node, the non-inverting output node being electrically connected to the inverting input node through the second capacitor, the inverting output node being electrically connected to the non-inverting input node through the first capacitor,
wherein the first differential signal has a voltage level including a first voltage level, a second voltage level higher than the first voltage level, a third voltage level higher than the second voltage level, and a fourth voltage level higher than the third voltage level,
wherein the third differential amplifier operates in a non-saturated region, when the voltage level of the first differential signal is in an input voltage range, and the third differential amplifier operates in a saturated region, when the voltage level of the first differential signal is out of the input voltage range, and
wherein the input voltage range is a voltage range from a first voltage value to a second voltage value, the first voltage value being set to be higher than the first voltage level and lower than the second voltage level, the second voltage value being set to be higher than the third voltage level and lower than the fourth voltage level.

2. The driving circuit according to claim 1,
wherein the first voltage level and the fourth voltage level are symmetrical with respect to an average voltage of the first differential signal, and the second voltage level and the third voltage level are symmetrical with respect to the average voltage of the first differential signal.

3. The driving circuit according to claim 1,
wherein the differential circuit comprises:
a first transistor having a base receiving the negative phase component of the second differential signal, an emitter electrically connected to the current source, and a collector outputting the first current;
a second transistor having a base receiving the positive phase component of the second differential signal, an emitter electrically connected to the current source, and a collector outputting the second current;
a third transistor having a base receiving a bias voltage, an emitter electrically connected to the collector of the first transistor, and a collector electrically connected to the first load resistor, and
a fourth transistor having a base receiving the bias voltage, an emitter electrically connected to the collector of the second transistor, and a collector electrically connected to the second load resistor.

4. A driving circuit to generate a driving signal for an optical modulator in response to a differential input signal having a positive phase component and a negative phase component, the driving circuit comprising:
a first differential amplifier configured to generate a differential output signal in response to a difference between the positive phase component and the negative phase component of the differential input signal, the differential output signal having a positive phase component and a negative phase component; and
a second differential amplifier configure to generate the driving signal in response to the differential output signal,
wherein the first differential amplifier comprises:
a current source configured to supply a source current;
a differential circuit configured to divide the source current into a first current and a second current, the first current and the second current varying complementarily in response to a difference between the positive phase component of the differential input signal and the negative phase component of the differential input signal;
a first load resistor configured to generate the positive phase component of the differential output signal based on the first current;
a second load resistor configured to generate the negative phase component of the differential output signal based on the second current; and
a delay adjustment circuit configured to delay the differential output signal in response to instantaneous voltage level of the differential output signal,
wherein the delay adjustment circuit comprises:
a first capacitor;
a second capacitor; and
a third differential amplifier having a non-inverting input node, an inverting input node, a non-inverting output node, and an inverting output node, the non-inverting input node being electrically connected between the first load resistor and the second differential amplifier, the inverting input node being electrically connected between the second load resistor and the second differential amplifier, the non-inverting output node being electrically connected to the inverting input node through the second capacitor, the inverting output node being electrically connected to the non-inverting input node through the first capacitor,
wherein the differential output signal has a voltage level including a first voltage level, a second voltage level higher than the first voltage level, a third voltage level higher than the second voltage level, and a fourth voltage level higher than the third voltage level,
wherein the third differential amplifier operates in a non-saturated region, when the voltage level of the differential output signal is in an input voltage range, and the third differential amplifier operates in a saturated region, when the voltage level of the differential output signal is out of the input voltage range, and
wherein the input voltage range is a voltage range from a first voltage value to a second voltage value, the first voltage value being set to be higher than the first voltage level and lower than the second voltage level, the second voltage value being set to be higher than the third voltage level and lower than the fourth voltage level.

5. The driving circuit according to claim 4,
wherein the first voltage level and the fourth voltage level are symmetrical with respect to an average voltage of the differential output signal, and the second voltage level and the third voltage level are symmetrical with respect to the average voltage of the differential output signal.

6. The driving circuit according to claim 4,
wherein the differential circuit comprises:
a first transistor having a base receiving the negative phase component of the differential input signal, an emitter electrically connected to the current source, and a collector outputting the first current;
a second transistor having a base receiving the positive phase component of the differential input signal, an emitter electrically connected to the current source, and a collector outputting the second current;
a third transistor having a base receiving a bias voltage, an emitter electrically connected to the collector of the first transistor, and a collector electrically connected to the first load resistor, and
a fourth transistor having a base receiving the bias voltage, an emitter electrically connected to the collector of the second transistor, and a collector electrically connected to the second load resistor.

7. The driving circuit according to claim 1,
wherein the first differential amplifier further includes:
a first inductor connected in series to the first load resistor; and
a second inductor connected to in series to the second load resistor.
